(19) United States
(12) Patent Application Publication
(10) Pub. No.: US 2023/0020157 A1
(43) Pub. Date: Jan. 19, 2023

(54) FILM WITH A COATING

(71) Applicant: Neutrino Deutschland GmbH, Berlin (DE)

(72) Inventor: Holger Thorsten Schubart, Berlin (DE)

(21) Appl. No.: 17/787,390

(22) PCT Filed: Dec. 10, 2020
(86) PCT No.: PCT/DE2020/000343

§ 371 Date: Jun. 20, 2022

(30) Foreign Application Priority Data
Dec. 23, 2019 (DE) 10 2019 008 982.0

(51) Int. Cl. C09D 1/00; C09D 5/24; B05D 3/06; B05D 3/00

(52) U.S. Cl. CPC C09D 1/00; C09D 5/24; B05D 3/06; B05D 3/007; C08K 2201/001; B82Y 30/00

(57) ABSTRACT

The interaction of elementary particles, in particular neutrinos of any kind and/or electromagnetic waves and/or gravitation, hereinafter referred to as kinetic energy of radiations, such as non-visible spectrum of solar or space radiation with metallic and/or non-metallic structures, in particular a film which is made of metal, a metal alloy or an electrically conductive plastic and which has a non-metallic nano-coating.

The invention relates to the interaction of elementary particles, in particular neutrinos of any type and/or electromagnetic waves and/or gravitation, designated hereinafter as kinetic energy of radiation, the non-visible spectrum of solar or space radiation with metallic and/or nonmetallic structures, in particular a film made from metal, a metal alloy or an electrically conductive plastics material and which has a nonmetallic nanocoating.

It is known that, unlike with other known elementary particles, in the event of said interaction, in particular of neutrinos with matter, only weak interaction processes occur. Therefore, as a rule the interaction reaction that occurs when neutrinos penetrate bodies of large dimensions and/or high density is only slight.

The penetration capability of neutrinos depends on their energy. With increasing energy, the effective cross section of the neutrinos increases and the average free wavelength decreases. The present invention assumes that the energy of the neutrinos is substantially a “constant” and turns towards the penetration part, the molecules of metallic and/or nonmetallic structures. It is known that a film as a surface portion of metal, a metal alloy with preferably a nanocoating of at least graphene and silicon enters into interaction with kinetic energy of radiation, in particular neutrinos, i.e. the molecules thereof, or atoms, under the action of elementary particles, in particular of neutrinos, start to enter into interaction therewith, in particular start to vibrate or to increase a vibrational amplitude of the molecules, or atoms of the coated film, which then enters into interaction with the substrate. This is described at least in part also as “atomic vibrations in nanomaterials” and is the prerequisite for drawing electrical energy from such metallic and/or nonmetallic structures, thus coated film, in the context of energy conversion.

WO 2016/142 056 A1 discloses a film made of a metallic substrate of a metal or a metal alloy, a backing film, which has a coating of at least graphene and silicon, wherein the coating is a nanocoating in which graphene and silicon are present as nanoparticles, wherein the coating includes 10% to 80% silicon or 20% to 90% graphene and the lattice structure of the nanocoating is compressed such that it results in an interaction of the molecules, or atoms of the nanocoating with kinetic energy of radiation, the non-visible spectrum of solar or space radiation, such as for example neutrinos, wherein the kinetic energy is tappable as direct current via the graphene as a positive terminal and the metallic substrate as a negative terminal. For the purposes of the invention, neutrinos should be understood to include anti-neutrinos.

It should also be mentioned that the coating has a nanotechnologically modified lattice structure. The modified and/or compressed lattice structure, for example doped graphene, serves to ensure that the above-described interaction is further optimized.

It is the object of the invention to increase the efficiency of such a coated structure and further develop the device. This object is achieved with the features of independent claims 1, 4 and 6. Advantageous embodiments constitute the subject matter of the subclaims.

According thereto, a film according to the invention has the following features:

The film of multilayer structure consists, as described above, of a substrate, which has a coating of at least graphene and silicon. The coating is a known nanocoating, containing graphene and silicon as nanoparticles. As a result of an interaction arising of the molecules, or atoms of the coating with kinetic energy of radiation, the non-visible spectrum of solar or space radiation, such as for example neutrinos, the molecules, or atoms or their constituents are excited to vibrate and an electron flow thus arises within the film. In this respect, a kinetic energy of the molecules, or atoms or their constituents, resulting from the interaction, is tappable as direct current via the coating as a positive terminal and the substrate as a negative terminal. According to the invention, the substrate consists wholly or in part of an electrically conductive plastics material, instead of metal or a metal alloy. This leads to a reduction in weight and may also reduce material costs.

For the purposes of the invention, film means a surface portion which is delimited according to its dimensions. The thickness of the film may amount to 0.01 mm to 4 mm, preferably 0.01 mm to 1 mm, particularly preferably 0.05 mm to 1 mm.

Provision is made for the coating to include 10% to 80% silicon and 20% to 90% graphene.

Provision is preferably made for the coating to include 10% to 50% silicon and 50% to 90% graphene. Provision is particularly preferably made for the coating to include 25% silicon and 75% graphene.

In one embodiment, the plastics substrate consists of two layers, wherein a second layer functions as an insulation layer and a first layer is electrically conductive. The coating is applied to the electrically conductive first layer. The second layer, which consists of an electrically non-conductive plastics material, is arranged on the side of the first layer opposite from the coating. This layer serves as an insulation layer, if a plurality of films are placed functionally on top of one another to form a stack, such that the respective superposed layers are delimitable from one another in an electrically insulated manner by the second layer acting as an insulation layer. The electrically conductive plastics material is, by way of example, an electrically conductive polymer or a modified thermoplastic.

The advantage of this structure consists in the fact that the insulation layer is integrated directly into the film and does not have to be applied in a separate working step.

A further aspect of the invention relates to a method for increasing the power of the film according to the invention. The power of the film, i.e. the electrical energy which can be drawn from the film according to the invention may be increased according to the invention if the film, when used functionally, is supplied with thermal energy, for example through sunlight or the warmth of a human body. The interaction of the molecules or atoms of the nanocoating, i.e. of the coating, with kinetic energy of radiation, the non-visible spectrum of solar or space radiation, such as for example neutrinos is increased, whereby the molecules, or atoms or their constituents are excited to greater vibration and increased electron flow thus arises within the film. The electrical power that can be drawn from the film is thus increased.

In this respect, the molecules, or atoms of the coating have an increased kinetic energy when thermal energy is supplied, thereby ensuring the amount of electrical power that can be drawn is increased.

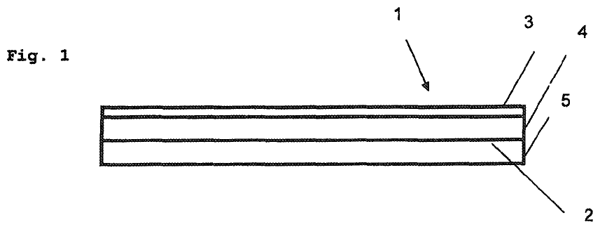

The invention is further explained below on the basis of an exemplary embodiment and with reference to FIG. 1. This reveals further advantages, features and embodiments of the invention.

In the Figure:

FIG. 1 is a schematic representation of a film according to the invention.

According thereto, the film 1 consists, as an extensive portion, of a substrate 2 having a coating 3 of at least graphene and silicon. According to the invention, the coating 3 is a nanocoating containing graphene and silicon as nanoparticles. Neutrinos passing through the film 1 and thus the coating 3 result in an interaction or collision of the molecules of the coating 3, wherein as a result of the interaction kinetic energy is tappable as direct current via the graphene as a positive terminal and the substrate as a negative terminal. The substrate 2 consists in part of an electrically conductive plastics material. It has two layers, a first layer 4 and a second layer 5. The first layer 4 is electrically conductive and the coating 3 is arranged thereon. The second layer 5, which consists of an electrically non-conductive plastics material, is arranged on the side of the first layer 4 opposite from the coating 3. This layer serves as an insulation layer, if a plurality of films 1 are placed functionally on top of one another to form a stack, such that the respective superposed layers are delimitable from one another in an electrically insulated manner by the second layer 5 acting as an insulation layer.

### LIST OF REFERENCE SIGNS

1. Film
2. Substrate
3. Coating
4. First layer
5. Second layer

1. A film (1) composed of a substrate (2), which has a coating (3) of at least graphene and silicon, the coating (3) being a nanocoating containing graphene and silicon as nanoparticles, thus resulting in an interaction of the molecules, or atoms of the coating (3) with kinetic energy of radiation, in particular neutrinos passing through, wherein kinetic energy of the molecules of the film (1) and therefore an electron flow within the film (1) is tappable as direct current via the coating (3) as a positive terminal and the substrate (2) as a negative terminal, wherein the substrate (2) consists wholly or in part of an electrically conductive plastics material.

2. The film (1) according to claim 1, wherein the substrate (2) of plastics material consists of two layers, wherein a first layer (4) is electrically conductive and a second layer (5) functions as an insulation layer and the second layer (5) is arranged on the side of the first layer (4) opposite from the coating (3).

3. The film (1) according to claim 1, wherein the electrically conductive plastics material is an electrically conductive polymer or a modified thermoplastic.

4. A film (1) composed of a substrate (2) of a metal, a metal alloy or an electrically conductive plastics material, which has a coating (3) of at least graphene and silicon, the coating (3) being a nanocoating containing graphene and silicon as nanoparticles, thus resulting in interaction of the molecules, or atoms of the coating (3) with kinetic energy of radiation, in particular neutrinos passing through, wherein kinetic energy of the molecules, or atoms of the film (1) and therefore an electron flow within the film (1) is tappable as direct current via the coating (3) as a positive terminal and the substrate (2) as a negative terminal, wherein the molecules of the coating (3) have an increased kinetic energy when thermal energy is supplied, thereby ensuring that the amount of electrical power that can be drawn from the film (1) is increased.

5. The film (1) according to claim 1, wherein the coating (3) includes 10% to 80% silicon and 20% to 90% graphene.

6. A method for generating electrical energy by means of a film (1) having the features according to claim 1, wherein the film (1) is supplied with thermal energy, whereby the kinetic energy of the molecules, or the atoms of the coating (3) is increased when the film (1) is supplied with thermal energy and therefore the interaction of the molecules, or of the atoms of the coating (3) with kinetic energy of radiation passing through, is increased and thus the electrical power that can be drawn from the film (1) is increased.

7. The film (1) according to claim 1, wherein the coating (3) includes 10% to 50% silicon and 50% to 90% graphene.

8. The film (1) according to claim 1, wherein the coating (3) includes 25% silicon and 75% graphene.

9. A method for generating electrical energy by means of a film (1) having the features according to claim 1, wherein the film (1) is supplied with thermal energy, whereby the kinetic energy of the molecules, or the atoms of the coating (3) is increased when the film (1) is supplied with thermal energy and therefore the interaction of the molecules, or of the atoms of the coating (3) with neutrinos passing through is increased and thus the electrical power that can be drawn from the film (1) is increased.

10. The film (1) according to claim 4, wherein the coating (3) includes 10% to 80% silicon and 20% to 90% graphene

11. The film (1) according to claim 4, wherein the coating (3) includes 10% to 50% silicon and 50% to 90% graphene.

12. The film (1) according to claim 4, wherein the coating (3) includes 25% silicon and 75% graphene.

13. A method for generating electrical energy by means of a film (1) having the features according to claim 1, wherein the film (1) is supplied with thermal energy, whereby the kinetic energy of the molecules, or the atoms of the coating (3) is increased when the film (1) is supplied with thermal energy and therefore the interaction of the molecules, or of the atoms of the coating (3) with neutrinos passing through is increased and thus the electrical power that can be drawn from the film (1) is increased.
